(19) United States
(12) Patent Application Publication
(10) Pub. No.: US 2018/0056435 A1
(43) Pub. Date: Mar. 1, 2018

(54) MULTI-SCALE MANUFACTURING OF CARBON NANOTUBE COMPOSITES

(71) Applicant: University of Connecticut, Farmington, CT (US)

(72) Inventor: Leila Ladani, Willington, CT (US)

(21) Appl. No.: 15/684,455

(22) Filed: Aug. 23, 2017

Related U.S. Application Data
(60) Provisional application No. 62/378,528, filed on Aug. 23, 2016.

(51) Int. Cl. B23K 15/00; C01B 32/162; C01B 32/168; C04B 35/80; C04B 35/628; C04B 35/653; C08J 5/00; B28B 1/00; B33Y 10/00; B33Y 80/00; B29C 64/153; B23K 26/342

(52) U.S. Cl. CPC B23K 15/0086; C01B 32/162; C01B 32/168; C04B 35/80; C04B 35/62844; C04B 35/653; H01L 23/53276; B28B 1/001; B33Y 10/00; B33Y 80/00; B29C 64/153; B23K 26/342; C08J 5/005

(57) ABSTRACT

The present invention relates, generally, to methods for manufacturing metal/polymer/ceramic carbon nanotube composite materials, including additive manufacturing techniques, more particularly, to a method for manufacturing metal-carbon nanotube composite comprising adding metal layer to nanotubes to make a nano-composite.

### CROSS-REFERENCE TO RELATED APPLICATIONS

The present application claims the benefit under 35 U.S.C. §119(e) to U.S. Provisional Patent Application 62/378,528, filed Aug. 23, 2016, and titled: Multi-Scale Manufacturing of Carbon Nanotube Composites, which is incorporated herein by reference in its entirety.

### GOVERNMENT LICENSE RIGHTS

This invention was made with government support under CMMI1415165 awarded by the National Science Foundation. The government has certain rights in the invention.

### BACKGROUND

### 1. Field of the Discovery

The present invention relates, generally, to methods for manufacturing carbon nanotube composite materials with metals, polymers and ceramics, including additive manufacturing techniques, more particularly, to a method for manufacturing metal-carbon nanotube composite comprising adding metal layer to nanotubes to make a nano-composite.

### 2. Background Information

Carbon nanotubes are of great interest since they exhibit unique and useful chemical and physical properties related to, for instance, their morphology, toughness, electrical and thermal conductivity and magnetic properties. Since their discovery, CNTs have been the subject of intensive research and numerous patents, scientific articles and books have been devoted to their synthesis, properties and applications (See, e.g., US20070148962A1). The carbon nanotube has excellent electrical conductivity, thermal conductivity and strength, and is expected to show more advantageous physical properties when combined with specific metals having particular characteristics. Therefore, there have been a lot of developments of CNT composites. For example, researchers are investigating metal-CNT composites in order to improve mechanical properties. Nanocomposites are mainly made in bulk form, for example, via a powder method or a sintering process.

Pure carbon nanotubes are formed at high temperature of 600-1000° C. via chemical vapor deposition (CVD). Surface treatment prior to the deposition is important to control the growing direction and speed of the pure carbon nanotube. The carbon nanotube does not constitute densely packed structure when it grows, leaving empty spaces between carbon nanotubes, which leads to issues in replacing the existing metal thin film material. There have been attempts to fill the empty spaces between the carbon nanotubes with, e.g., SiO₂, to use as semiconductor interconnections.

Metal/CNT nano-composite have been formed in past in the type of thin film by simultaneously depositing metal and carbon nanotubes by electroplating (Method for manufacturing metal/carbon nanotube nano-composite using electroplating, Ser. No. 11/589,305, Oct. 30, 2006). Densely packed structures unlike those observed by growth of pure carbon nanotubes can be obtained, and depositions of thin metal films are obtained. Thus, all the metal thin films including the existing semiconductor metal interconnection can be replaced, improving their electrical, mechanical and thermal physical properties. However, the electroplating method is associated with several issues including, metal deposition is uneven, uncontrolled metal density, and defects in the deposition layers.

Another method for making a CNT/metal nanoparticle composite includes mixing a solution containing precious metal ions and a solution containing a soluble polymer to obtain a first mixture, and admixing that with a solution containing carbon nanotubes, and irradiating the mixture with a radiation having a wave length less than 450 nm (See, e.g., US 2010/0255290 A1). This method utilizes water soluble polymers to attach the metal particles to carbon nanotubes.

Yet another method of forming a carbon nanotube composite material includes the steps of dispersing CNTs in a polar solvent, including water or a C1-C3 alcohol, and introducing metal cations and carbonate anions into the polar solvent containing dispersed carbon nanotubes, and co-precipitating metal cation-carbonate and carbon nanotubes, thereby forming a carbon nanotube composite material comprising Me-carbonate.

However, the CNT composite materials produced by currently known methods do not demonstrate electrical and/or mechanical properties that are significantly better than metals. Therefore, the available methods may be able to produce a material, but the product may not be of much interest because of lack of desired nanotube and metal properties.

As such, there is a need in the art for a reliable and reproducible method for making CNT-metal nanoparticle composite materials with controlled deposition in terms of density, thickness and geometry, and without any chemical treatment, in order to preserve the desirable properties of the metal and carbon nanotubes.

### SUMMARY

The present description provides methods of making a CNT composite materials, e.g., metal-carbon nanotube, polymer-carbon nanotube and ceramic-carbon nanotube composite materials, with controlled density and geometry. The CNT composite materials produced according to the methods as described herein have at least one of greater ampacity, higher conductivity, lower weight, controlled geometry, or tunable properties as compared to predicate materials.

In one aspect, the description provides a method comprising, growing a carbon nanotube in through deposition of a catalyst on a substrate to activate the substrate surface; depositing a nanoscale layer of at least one of metal, polymer, ceramic or a combination thereof on the carbon nanotube material; depositing a powder particle layer of at least one of metal, polymer, ceramic or a combination thereof, over the nanoscale layer; and melting the at least one of metal, polymer, ceramic or a combination thereof particles in a preselected geometric pattern, thereby forming a metal and/or polymer film with the selected geometric pattern, wherein the metal and/or polymer film penetrates into the interstices between individual carbon nanotube strands to form a carbon nanotube and metallic and/or polymeric composite having the selected geometric pattern.

In certain embodiments, the step of growing a carbon nanotube includes growing the CNTs in a particular orientation. In certain embodiments, the orientation is vertical.

In certain embodiments, the step of depositing a nanoscale layer of at least one of metal, polymer, ceramic or a combination thereof, on the carbon nanotube material is performed using a micro-fabrication deposition technique.

In certain embodiments, the step of melting the at least one of metal, polymer, ceramic or a combination thereof particles is performed using an additive manufacturing technique, thereby forming film with a predetermined and/or a selected geometric pattern.

The preceding general areas of utility are given by way of example only and are not intended to be limiting on the scope of the present disclosure and appended claims. Additional objects and advantages associated with the compositions, methods, and processes of the present invention will be appreciated by one of ordinary skill in the art in light of the instant claims, description, and examples. For example, the various aspects and embodiments of the invention may be utilized in numerous combinations, all of which are expressly contemplated by the present description. These additional advantages objects and embodiments are expressly included within the scope of the present invention. The publications and other materials used herein to illuminate the background of the invention, and in particular cases, to provide additional details respecting the practice, are incorporated by reference.

### BRIEF DESCRIPTION OF DRAWINGS

The accompanying drawings, which are incorporated into and form a part of the specification, illustrate several embodiments of the present invention and, together with the description, serve to explain the principles of the invention. The drawings are only for the purpose of illustrating an embodiment of the invention and are not to be construed as limiting the invention. Further objects, features and advantages of the invention will become apparent from the following detailed description taken in conjunction with the accompanying figures showing illustrative embodiments of the invention, in which:

FIG. 1 represents the steps for fabrication of CNT-Cu composite material.

FIG. 2a represents a proposed technology of a wafer substrate with CNTs grown vertically on the surface placed in powder bed.

FIG. 2b represents a blown up image of the CNTs with copper powder particles on top, light shade shows the copper layer deposited using nanoscale processes.

FIG. 2c represents a close-up image shows the nanoscale deposited copper penetrates between CNTs creating points for capillary action.

FIG. 2d represents a laser beam melting the powder particles.

FIG. 2e represents a blown up image of the copper diffusing in between the CNTs to make a matrix.

FIG. 3a represents CNTs grown on a surface of wafer.

FIG. 3b represents CNTs grown on a surface of wafer with different magnification.

FIG. 3c represents CNTs plated using electron beam evaporation to deposit the nanolayer activating copper.

FIG. 4 represents simulation of electron beam melting process for copper material at 1000 W and beam speed of 0.05 m/s.

### DETAILED DESCRIPTION

The following is a detailed description provided to aid those skilled in the art in practicing the present invention. Those of ordinary skill in the art may make modifications and variations in the embodiments described herein without departing from the spirit or scope of the present disclosure. All publications, patent applications, patents, figures and other references mentioned herein are expressly incorporated by reference in their entirety.

The description provides methods for forming carbon nanotube-metal composite materials. Surprisingly and unexpectedly it was discovered that the processes as described herein can produce composites having a number of advantageous features over the art. In particular, relative to the currently available materials, the composite materials produced according to the described methods have at least one of greater ampacity, higher conductivity, lower weight, controlled geometry, tunable properties or a combination thereof.

Individual carbon atoms in CNTs have very strong bond with the neighboring carbon atoms, but typically do not bond with any other external material. Therefore, metals or other materials, e.g., polymeric materials, do not bond with carbon in CNTs. Therefore, making a composite metallic material with high percentage of carbon is almost impossible through traditional manufacturing processes. Prior art approaches of mixing the CNTs with molten material do not really provide uniform results. Other techniques such as electrodeposition of metals on carbon nanotubes have yielded poor results and large defect density.

Thus, the present description provides methods that address one or more of the above-mentioned shortcomings in the art. In particular, the description provides processes of making multifunctional metal, polymer, ceramic or combination thereof-CNT composite materials with controlled density, thickness and geometry by adapting micro-fabrication as well as additive manufacturing technologies. The description discloses that CNT composite materials made using multi-scale manufacturing methods as described herein preserve the extraordinary properties of CNTs (e.g. ampacity or conductivity), and the final composite material properties including density and geometry can be “tuned”, and controlled closely.

Density of the composite material depends on the factors including but not limited to substrate material, orientation of the CNTs, ratio of CNTs/substrate, ratio of CNTs/metal, application of the CNT composites and the mico-fabrication technique. Depending on any of the above mentioned factors, density of the CNT composite material could vary between CNTs and the substrate wherein substrate material includes but is not limited to metal, polymer or ceramics.

Unless otherwise defined, all technical and scientific terms used herein have the same meaning as commonly understood by one of ordinary skill in the art to which this invention belongs. The terminology used in the description is for describing particular embodiments only and is not intended to be limiting of the invention.

Where a range of values is provided, it is understood that each intervening value, to the tenth of the unit of the lower limit unless the context clearly dictates otherwise (such as in the case of a group containing a number of carbon atoms in which case each carbon atom number falling within the range is provided), between the upper and lower limit of that range and any other stated or intervening value in that stated range is encompassed within the invention. The upper and lower limits of these smaller ranges may independently be included in the smaller ranges is also encompassed within the invention, subject to any specifically excluded limit in the stated range. Where the stated range includes one or both of the limits, ranges excluding either both of those included limits are also included in the invention.

The following terms are used to describe the present invention. In instances where a term is not specifically defined herein, that term is given an art-recognized meaning by those of ordinary skill applying that term in context to its use in describing the present invention.

The articles “a” and “an” as used herein and in the appended claims are used herein to refer to one or to more than one (i.e., to at least one) of the grammatical object of the article unless the context clearly indicates otherwise. By way of example, “an element” means one element or more than one element.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.”

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

As used herein in the specification and in the claims, the phrase “at least one,” in reference to a list of one or more elements, should be understood to mean at least one element selected from anyone or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, in certain methods described herein that include more than one step or act, the order of the steps or acts of the method is not necessarily limited to the order in which the steps or acts of the method are recited unless the context indicates otherwise.

The term “micro-fabrication” as used herein can mean but is in no way limited to technologies which are utilized in depositing material and developing patterns for manufacturing devices.

The term “additive manufacturing technique” as used herein can mean but is in no way limited to a process by which digital 3D design data is used to build up a component in layers by depositing material. The term “3D printing” is increasingly used as a synonym for additive manufacturing. However, the latter is more accurate in that it describes a professional production technique which is clearly distinguished from conventional methods of material removal. Instead of milling a workpiece from solid block, for example, additive manufacturing builds up components layer by layer using materials which are available in fine powder form. As would be appreciated by the skilled artisan, a range of different metals, plastics and composite materials may be used.

The term “composite material” as used herein can mean but is in no way limited to a material made from two or more constituent materials with significantly different physical or chemical properties that, when combined, produce a material with characteristics different from the individual components.

In one aspect, the description provides methods of making a metal-carbon nanotube (CNT) composite material, the method comprising: depositing a catalyst on a substrate, wherein the catalyst activates the substrate surface; growing a CNT material on the substrate; depositing a nanoscale layer of metal on the CNT material; depositing a metal powder particle layer over the nanoscale metal layer; and melting the metal powder particles in a preselected geometric pattern, thereby forming a metal film with the selected geometric pattern, wherein the metal film penetrates into the interstices between individual CNT strands to form a CNT-metallic composite material having the selected geometric pattern.

In certain embodiments, the step of growing a carbon nanotube includes growing the CNTs in a particular orientation. In certain embodiments, the orientation is vertical.

In certain embodiments, the step of depositing a nanoscale layer of metal on the carbon nanotube material is performed using a micro-fabrication deposition technique.

In certain embodiments, the step of melting the metal powder particles in a preselected geometric pattern is performed using an additive manufacturing technique, thereby forming metal film with a predetermined and/or a selective geometric pattern.

In another aspect, the description provides methods of making a polymer-carbon nanotube composite, the method comprising: depositing a catalyst on a substrate; growing a CNT material on the substrate; depositing a nanoscale layer of polymer on the carbon nanotube material; depositing a polymer powder particle layer over the nanoscale metal layer; and melting the polymer powder particles in a preselected geometric pattern, thereby forming a polymer film with the selected geometric pattern, wherein the polymer film penetrates into the interstices between individual CNT strands to form a CNT-polymer composite material having the selected geometric pattern.

In certain embodiments, the step of growing a carbon nanotube includes growing the CNTs in a particular orientation. In certain embodiments, the orientation is vertical.

In certain embodiments, the step of depositing a nanoscale layer of polymer on the carbon nanotube material is performed using a micro-fabrication deposition technique.

In certain embodiments, the step of depositing and melting the polymer powder particles is performed using an additive manufacturing technique, thereby forming a polymer film with a predetermined and/or a selective geometric pattern.

In another aspect, the description provides methods of making a ceramic-carbon nanotube composite, the method comprising: depositing a catalyst on a substrate; growing a CNT material on the substrate; depositing a nanoscale layer of ceramic material on the carbon nanotube material; depositing a ceramic particle powder layer over the nanoscale ceramic layer; and melting the ceramic particle powder in a preselected geometric patter, thereby forming a ceramic film with the selected geometric pattern, wherein the ceramic film penetrates into the interstices between individual CNT strands to form a CNT-ceramic composite material having the selected geometric pattern.

In certain embodiments, the step of growing a carbon nanotube includes growing the CNTs in a particular orientation. In certain embodiments, the orientation is vertical.

In certain embodiments, the step of depositing a nanoscale layer of ceramic on the carbon nanotube material is performed using a micro-fabrication deposition technique.

In certain embodiments, the step of melting the ceramic particle powder layer is performed using an additive manufacturing technique, thereby forming a ceramic film with a predetermined and/or a selected geometric pattern.

In any of the aspects or embodiments described herein, the components of the composite can be mixed to create additional composites, e.g., metal-polymer CNT composite.

In any of the aspects or embodiments described herein, the carbon nanotube composite material has a density from about 1 g/cm³ to 25 g/cm³.

In some embodiments, metal-carbon nanotube composite material has a density from about 1 g/cm³ to 25 g/cm³.

In some embodiments, polymer-carbon nanotube composite material has a density from about 1 g/cm³ to 25 g/cm³.

In some additional embodiments, ceramic-carbon nanotube composite material has a density from about 1 g/cm³ to 25 g/cm³.

In any of the aspects or embodiments described herein, the substrate can be any material including but not limited to Al2O3, silicon, SiO2, polymers, ceramics, a metal or a metal oxide.

In any of the aspects or embodiments described herein, the catalyst comprises Ni, Fe, Co, Pt, Pd or a metal catalyst.

In any of the aspects or embodiments described herein, depositing the nanoscale metal or polymer layer comprises applying metal or the polymer material using at least one of the micro-fabrication process including the sputtering, e-beam evaporation, an atomic layer deposition, a chemical vapor deposition process, and a physical vapor deposition process or a combination thereof.

In some embodiments described herein, depositing the metal film comprises applying at least one of Ag, Mg, Ca, Sr, Ba, Mn, Fe, Co, Ni, Cu, Zn, Cd, Sn, Pb, Au, Sc, Y, La, Ce, Pr, Nd, Pm, Sm, Eu, Gd, Tb, Dy, Ho, Er, Tm, Yb, Lu, and Cr or any other metal onto the carbon nanotube material.

In some embodiments described herein, the metal-carbon nanotube composite has increased ampacity or conductivity and reduced electrical resistance.

In any of the aspects or embodiments described herein, the additive manufacturing technique comprises electron beam melting and laser beam melting techniques

In any of the aspects or embodiments described herein, the additive manufacturing technique is selective to provide a predetermined and selective geometric pattern.

Additive manufacturing (AM) techniques rely on a layered approach to building a metal or plastic part or component from the bottom up. Also referred to as 3D printing, additive manufacturing can be used to create extremely complex parts very quickly. A heat source is used to heat each layer, typically by raster scanning the heat source back and forth across sections of the layer. The heat source melts the powdered material forming the layer and then a subsequent layer of powdered material is laid down and heated. These operations are alternately repeated for the layers L1-Ln and the resulting finished part is thus made up of a plurality of layers, one melted on top of the previous one. Thus, a part made from the AM process is typically constructed of a large plurality of distinct layers of material.

In any of the aspects or embodiments described herein, the CNT is grown oriented in vertical direction.

Some embodiments described herein disclose a method of making a metal-carbon nanotube composite, the method comprising: depositing a metal catalyst on Al₂O₃; growing a CNT material on Al₂O₃; depositing a nanoscale layer of copper using, e.g., a chemical/physical vapor deposition technique, sputtering, e-beam evaporation or atomic layer deposition to form a copper film, and depositing a copper powder particle layer; and melting it to forma a copper film, e.g., using electron beam melting/laser beam melting additive manufacturing technologies, wherein the copper film penetrates into the interstices between individual carbon nanotube strands to form a carbon nanotube and copper composite.

Another aspect described herein discloses a carbon nanotube composite material as described herein or produced according to a method described herein, comprising at least one of a metal, polymer, ceramic or combination thereof. Other embodiments describe the composite material wherein, the substrate includes but is not limited to Al2O3, silicon, SiO2, polymers, ceramics, a metal or a metal oxide.

Yet another embodiment describes the composite material wherein, depositing the metal film comprises applying at least one of aluminum, nickel, copper, titanium, silver, gold, chromium or any other metal onto the carbon nanotube material.

### EXAMPLES

The first step of the process is to grow carbon nanotube on the substrate. This process is not unique and can be done using several different techniques such as plasma enhance chemical vapor (PECVD) deposition or thermal CVD. Not all substrate materials can be used easily. CNTs tend to grow better on Al₂O₃ material. So the preferred method is to grow Al₂O₃ on the surface. The next step is to deposit the catalyst which could be Ni, Fe or Co. After that the precursor will be used in PECVD or thermal CVD to grow CNTs. The temperature and pressure must be controlled very closely in order to achieve high quality CNTs. CNTs length and density can be adjusted based on the final application.

After this point, the wafers are placed within the sputtering, e-beam evaporation or atomic layer deposition machine to deposit a nanoscale layer of copper on top of CNTs. Deposition of an atomic layer of copper will activate the surface of the CNTs.

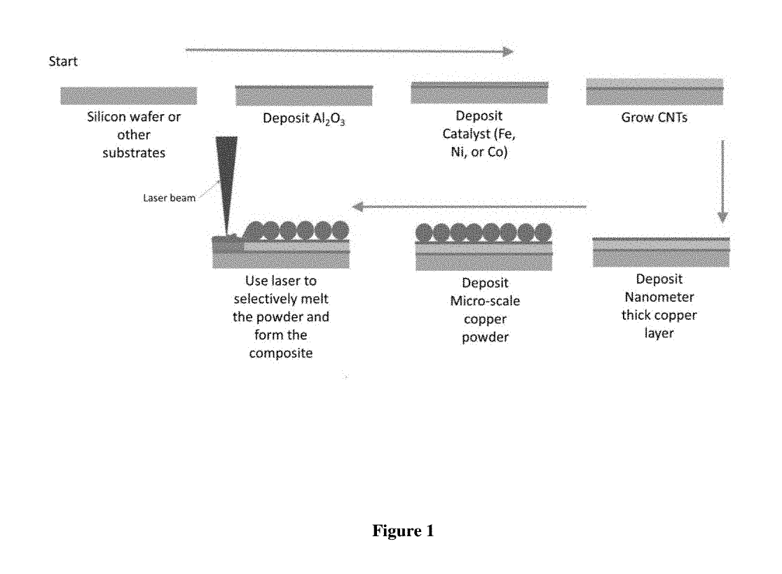

After that the substrates are taken out of the chamber and placed within a laser melting powder bed machine. Exemplary micro-fabrication steps are provided in FIG. 1.

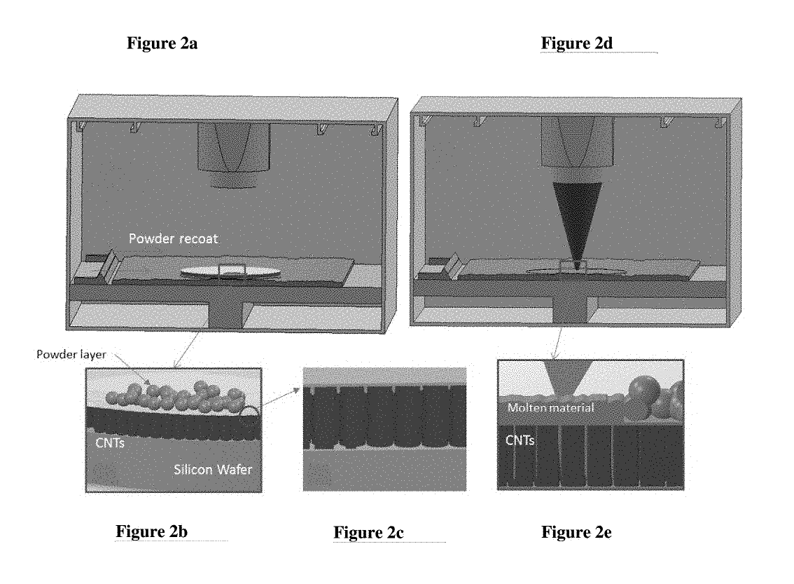

Important to the process is the step of melting, e.g., using a laser beam, the Cu particles on the substrate which is shown in FIG. 2a-2e. The layer of metallic powder is spread on top of the CNTs and then a laser or electron beam is used to melt the powder particles and make the composite material.

The substrate with CNTs on top is placed within the chamber. In laser or electron beam melting technologies, a powder layer of thickness of about 20 microns is spread on top of the CNTs. At the next step the laser or electron beam is used to melt the powder and create a uniform composite material in a certain pattern. As the laser heats up the surface to melt the copper powder particles, it also melts the pre-deposited nanoscale layer, which then infiltrates in between the CNTs due to the capillary action and pulls the rest of molten copper with it. If given enough time, this process could result in filling all the cavities in between the CNTs. The molten material will diffuse in between the CNTs strands and create a composite material with low weight. Depending on the orientation of CNTs, the composite will have certain properties in certain direction. For example, if CNTs are oriented perpendicular to the surface of the substrate, through thickness ampacity will be very high.

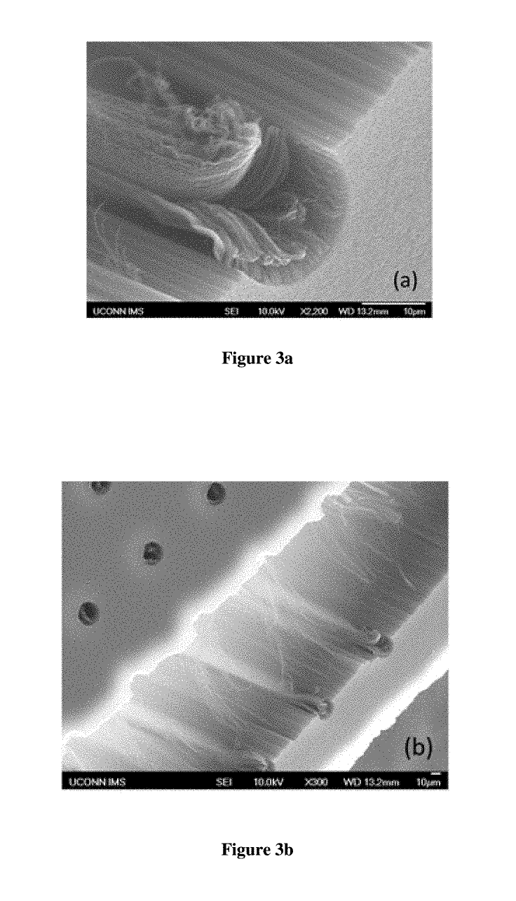

The process has been completed to the point where the nanoscale layer of copper is deposited on the CNTs. In other words, oriented and dense CNTs were successfully grown on the surface and nanoscale copper layer was deposited the on them. FIG. 3a-3c show some of the results.

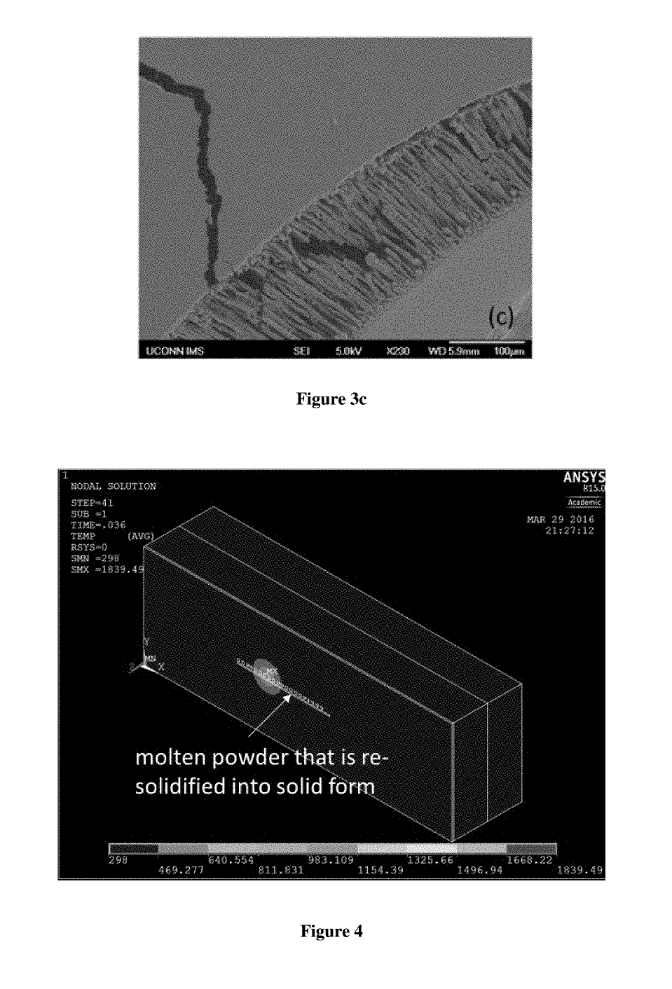

In addition to the experiment, simulation is conducted to determine the optimum process parameters for melting copper material using electron beam melting process. A Finite element (FE) simulation of the electron beam melting process is conducted and process parameters are varied to the point where successful melt pool is formed (at beam power of 1000 W and speed of 0.05 m/s). Due to high conductivity of copper and its relatively high melting temperature, large amount of power is needed in order to melt. However, with advances made in the area of electron beam melting where electron beam power easily exceeds 3000 W, it is possible to fabricate copper. Close control of the process is required to adjust the power and speed to allow enough exposure time for melting to occur. FIG. 4 shows the finite element simulation and formation of melt pool and re-solidification as it occurred in the simulation.

Composite materials have many different applications including aerospace industry. Additionally, because of multi-functionality nature of these composites, they will be very applicable to microelectronics of other electrical applications. For example, a combination of CNTs and polymers can produce conductive polymers that are used as interconnects and joint material in microelectronics (e.g. die attach, flat panel displays, hybrid and flexible electronics). Metallic composites are also of interest.

Another application of the composite materials is there use for through silicon vias (TSVs) in 3-dimensional integrated circuits. TSVs are currently made of copper. However, as the size of TSVs reduced to nanoscale, the resistance of copper increases and electro-migration issues arise. Use of this type of composite material will remove the electro-migration issues with very high ampacity that they provide. For example, copper-CNT composite material was found to have 100 times higher ampacity than copper alone.

Additional applications of the materials as described herein may include conductive interconnections and coatings for the electronics and aerospace industries. Smaller electronics will need to move to a different material with higher ampacity. In applications where there is need for conductive coatings, industry typically uses metals. Metallic coatings are typically very heavy. Thus, the present materials can provide a high quality solution that has even higher ampacity and much lower weight.

CNT-containing composite materials are expected to be important in the development of electronic devices such as field emission displays (FEDs) and field effect transistors (FETs).

Metal-CNT composites increase the current conductivity and ampacity limits of current materials such as metals. Metal-CNT composite also provides a lower weight option than metals. Lower weight translates into less energy consumption and thus saving money and reducing the carbon footprint of aerospace applications. In case of using it as interconnects, this product is expected to improve the reliability of interconnects and increase the life expectancy which will then reduce the costs.

As described herein, advantages achieved with the disclosed methods include metal-CNTs with at least one of the following properties:
i. High conductivity
ii. High ampacity
iii. Low weight
iv. Feasibility of producing in any layout using the 3d printing approach
v. Flexibility of design
vi. Possibility of controlling and tailoring the properties very closely.

Those skilled in the art will recognize, or be able to ascertain using no more than routine experimentation, many equivalents to the specific embodiments of the invention described herein. Such equivalents are intended to be encompassed by the following claims. It is understood that the detailed examples and embodiments described herein are given by way of example for illustrative purposes only, and are in no way considered to be limiting to the invention. Various modifications or changes in light thereof will be suggested to persons skilled in the art and are included within the spirit and purview of this application and are considered within the scope of the appended claims. For example, the relative quantities of the ingredients may be varied to optimize the desired effects, additional ingredients may be added, and/or similar ingredients may be substituted for one or more of the ingredients described. Additional advantageous features and functionalities associated with the systems, methods, and processes of the present invention will be apparent from the appended claims. Moreover, those skilled in the art will recognize, or be able to ascertain using no more than routine experimentation, many equivalents to the specific embodiments of the invention described herein. Such equivalents are intended to be encompassed by the following claims.

1. A method of making a metal-carbon nanotube composite material, the method comprising:
depositing a catalyst on a substrate, wherein the catalyst activates the substrate surface;
growing a carbon nanotube (CNT) material on the substrate;
depositing a nanoscale layer of metal on the carbon nanotube material;
depositing a metal powder particle layer over the nanoscale metal layer; and
melting the metal powder particles in a preselected geometric pattern, thereby forming a metal film with the selected geometric pattern, wherein the metal film penetrates into the interstices between individual carbon nanotube strands to form a carbon nanotube and metallic composite having the selected geometric pattern.

2. The method of claim 1, wherein the metal-carbon nanotube composite material has a density from 1 g/cm³ to 25 g/cm³.

3. The method of any claim 1, wherein additive manufacturing technique is selected from the group consisting of electron beam melting, laser beam melting, and a combination thereof.

4. The method of claim 1, wherein the substrate is Al₂O₃, SiO2, silicon, metal, polymer, ceramics, or a metal oxide.

5. The method of claim 1, wherein the catalyst comprises Ni, Fe, Co, Pt, Pd or a metal catalyst.

6. The method of claim 1, wherein the microfabrication technique is selected from the group consisting of electron beam evaporation, sputtering, vapor deposition, e-beam evaporation, atomic layer deposition, chemical vapor deposition, or physical vapor deposition and a combination thereof.

7. The method of claim 1, wherein depositing the metal powder, polymer powder or ceramic powder layer comprises using additive manufacturing techniques.

8. The method of claim 1, wherein depositing the metal film comprises applying at least one of aluminum, nickel, copper, titanium, silver, gold, chromium or any other metal onto the carbon nanotube material.

9. The method of claim 1, wherein the composite product has increased ampacity, electrical conductivity, thermal conductivity and reduced electrical resistance.

10. The method of claim 7, wherein the additive manufacturing technique comprises electron beam melting/laser beam melting.

11. The method of claim 10, wherein the additive manufacturing technique is selective to provide a predetermined, controlled geometric pattern.

12. The method of 1, wherein the CNTs are grown oriented in a preselected direction.

13. The method of claim 12 wherein, the CNTs are grown in vertical direction

14. A method of making a metal-carbon nanotube composite, the method comprising:
depositing a metal catalyst on Al₂O₃;
growing a CNT material on Al₂O₃;
depositing a nanoscale layer of copper powder using a chemical vapor deposition technique; sputtering, e-beam evaporation or atomic layer deposition to form a copper film and melting the copper using electron beam melting/laser beam melting additive manufacturing technologies, wherein the copper film penetrates into the interstices between individual carbon nanotube strands to form a carbon nanotube and copper composite.

15. A carbon nanotube composite material formed according to claim 14.

16. The composite material according to claim 15, wherein the composite material comprises metal-carbon nanotube.

17. The composite material according to claim 15, wherein the catalyst comprises Ni, Fe, Co, Pt, Pd or a metal catalyst.

18. The composite material according to claim 15, wherein the substrate is Al₂O₃, silicon, a metal, or a metal oxide.

19. The composite material according to claim 15, wherein the deposited metal film comprises at least one of aluminum, nickel, copper, titanium, silver, gold, chromium or any other metal onto the carbon nanotube material.

20. The composite material according to claim 15, wherein the composite material is a polymer-carbon nanotube composite.

21. The composite material according to claim 15, wherein the composite material is a ceramic-carbon nanotube composite.

22. The composite material according to claim 15, wherein the composite material has a density between 1 g/cm³ and 25 g/cm³.

23. A method of making a polymer-carbon nanotube composite, the method comprising:
depositing a catalyst on a substrate;
growing a CNT material on the substrate;
depositing (fabricating) a nanoscale layer of polymer on the carbon nanotube material using a micro-fabrication technique;
depositing a polymer powder particle layer over the nanoscale polymer layer; and
melting the polymer powder particle layer in a preselected geometric pattern using an additive manufacturing technique, thereby forming a polymer film with the selected geometric pattern, wherein the polymer film penetrates into the interstices between individual carbon nanotube strands to form a carbon nanotube and polymer composite with the selected geometry.

24. A method of making a ceramic-carbon nanotube composite, the method comprising:
depositing a catalyst on a substrate;
growing a CNT material on the substrate;
depositing (fabricating) a nanoscale layer of ceramic material on the carbon nanotube material using a micro-fabrication technique;
depositing a ceramic powder particle layer over the nanoscale ceramic layer; and
melting the ceramic powder particle layer in a preselected geometric pattern using an additive manufacturing technique, thereby forming a ceramic film with the selected geometric pattern, wherein the ceramics film penetrates into the interstices between individual carbon nanotube strands to form a carbon nanotube and ceramics composite with the selected geometry.

25. The method of claim 23, wherein the polymer-carbon nanotube composite material has a density from 1 g/cm³ to 25 g/cm³.

26. The method of claim 24, wherein the ceramics-carbon nanotube composite material has a density from 1 g/cm³ to 25 g/cm³.
